(19) United States
(12) Patent Application Publication
(10) Pub. No.: US 2007/0128838 A1
(43) Pub. Date: Jun. 7, 2007

(54) Method for producing SOI substrate and SOI substrate

(75) Inventor: Yoshiro Aoki, Tokyo (JP)

Correspondence Address: KOLISCH HARTWELL, P.C., 200 PACIFIC BUILDING, 520 SW YAMHILL STREET, PORTLAND, OR, 97204, US

(73) Assignee: Sumco Corporation

(21) Appl. No.: 11/700,469

(22) Filed: Jan. 30, 2007

(30) Foreign Application Priority Data
Jul. 20, 2004 (JP) 2004-211821

(51) Int. Cl. H01L 21/00

(52) U.S. Cl. 438/480

(57) ABSTRACT

A method for producing an SOI substrate, comprising: implanting oxygen ions into a silicon substrate; heat treating the silicon substrate in an inert atmosphere containing oxygen; and forming a buried oxide film in the silicon substrate, wherein the inert gas contains argon and nitrogen.

### BACKGROUND OF THE INVENTION

1. Field of the Invention

The present invention relates to a method for producing an SOI substrate and an SOI substrate, specifically relates to an SOI substrate comprising a silicon substrate and an insulation layer consisting of a buried oxide film in the substrate which has been formed by an oxygen implantation into a silicon substrate and subsequent heat treatment of the silicon substrate.

2. Description of Related Art

An SOI (Silicon on Insulator) substrate has a structure comprising a silicon base layer, an insulation layer which consists of buried oxide film formed on one side of the silicon base layer, and a silicon layer formed on the insulation layer at the side opposite to the silicon base layer.

A SIMOX (Separation by Implanted Oxygen) method is a method for producing such an SOI substrate, wherein the insulation layer consisting of buried oxide film, namely the buried oxide (BOX) layer, is formed by an implantation of oxygen ions into a silicon substrate and subsequent heat treatment. At present, the following two methods are generally used as the method for producing an SOI substrate according to the SIMOX method.

In one method, the formation of an SOI substrate is performed by: implanting oxygen ions into a silicon substrate using an acceleration energy of 180 keV so as to achieve an oxygen density of about 4×10¹⁷ atoms/cm²; heat treating the silicon substrate in an argon atmosphere containing oxygen of less than 1% so as to achieve a theoretical thickness calculated from the dosage of oxygen ions; and further heat treating the substrate in an argon atmosphere containing oxygen of not less than 1%, thereby increasing the film thickness of the BOX layer (Patent Reference 1: Japanese Unexamined Patent Application, First Publication No. H7-263538; pages 5-6 and FIG. 1). The SOI substrate produced by the above-described method is a type of SIMOX substrate and is called an ITOX (Internal Thermal Oxidation)-SIMOX.

In another method, implantation of oxygen into a silicon wafer is performed by a two-step process (Patent Reference 2: U.S. Pat. No. 5,930,643; column 5 to 6 of the specification). In the first step of this method, oxygen ions are implanted into the silicon substrate while heating the silicon substrate. In the second step, oxygen ions are implanted into the substrate which has been cooled to nearly a room temperature. In the first step of the oxygen implantation, since the silicon substrate is in a heated state, the surface of the substrate maintains a single crystalline structure. In the second step, an amorphous layer is formed on the silicon substrate by the oxygen implantation into the silicon substrate maintained at nearly a room temperature. After the above-described two-step ion implantation, the silicon substrate is subjected to an oxidization treatment by a heat treatment in a mixed gas atmosphere of argon and oxygen, thereby an SOI structure is formed in the substrate.

In the above-described method performing the two-step ion implantation, by the heat treatment, high defect density layer comprising polycrystalline grain boundaries, twin boundaries, and stacking faults is formed in the amorphous layer which has been formed by the second oxygen ion implantation step. Since the oxygen diffuses with a relatively high rate in the high defect density layer, the thickness of the BOX layer may be increased to a level about twice the theoretical thickness expected from the dosage of oxygen ions. Therefore, it is possible to improve the dielectric voltage of the BOX layer. A SIMOX wafer produced by this method is called an MLD (Modified Low Dose) SIMOX.

Moreover, there is a proposed method wherein a mixed gas of nitrogen and oxygen is used as an atmosphere for a heat-up step of a heat treatment, and the atmosphere is converted to the mixed gas of argon and oxygen in a step for retention at a constant temperature, and subsequent step of the heat treatment (Patent reference 3: Japanese Unexamined Patent Application First Publication No. 2002-319666; page 3 and FIG. 2). This method is intended to obtain the following effects. By converting the species of atmospheric gas between the heat-up step and the subsequent step including the retention step, interstitial silicon atoms (silicon atoms as interstitial atoms) are reduced by diffusion of vacancies (atomic vacancies), and therefore defects are reduced. In addition, formation of nitroxides by nitrogen diffusion in the silicon substrate during the heat treatment is inhibited.

In the conventionally used atmosphere for the heat treatment, nitrogen gas has been used as an inert gas, and oxygen was mixed with the nitrogen gas. However, the use of the mixed gas of nitrogen and oxygen has included problems such as diffusion of nitrogen into the silicon substrate forming nitroxide and increasing the surface roughness of the silicon layer (roughness of a surface of the silicon layer) of the SOI substrate. Therefore, at present, as described in the methods described in patent reference 1 and 2, in order to reduce the surface roughness of the SOI substrate, a mixed gas composed of Ar as an inert gas and oxygen mixed with the argon is generally used.

However, even when the mixed gas of argon and oxygen is used, in a heat treatment at a high temperature of 1100° C. or more, the surface roughness of the silicon layer of the SOI substrate is increased compared with the surface roughness of the silicon layer of the SOI substrate before the heat treatment. It is considered that the above-described rouhgning is caused by the sublimation of SiO from the oxide film.

Moreover, as a result of the inventors production of MLD-SIMOX, in accordance with the proposal of Patent Reference 3, by using the mixed gas of nitrogen and oxygen as the atmosphere during the heat-up process, and converting the atmosphere to the mixed gas of argon and oxygen during and after the retention process at a constant temperature, it was found that diffusion of nitrogen into the silicon substrate occurred and the surface roughness of the silicon layer was increased even though the nitrogen was only used in the heat-up process of the heat treatment.

A large surface roughness of the silicon layer of the SOI substrate after the heat treatment is not desired. For example, when the SOI substrate is subjected to examination of particles adhered to the surface of the silicon layer, a large surface roughness of the silicon layer deteriorates detection precision of the particles. Therefore, there is a demand for reduction of surface roughness of the silicon layer to as close a level as that of the silicon layer before the heat treatment.

In order to satisfy the above-described demand, a heat treatment method in a pure oxygen atmosphere composed of 100% of oxygen (Patent Reference 4: U.S. Pat. No. 5,930,643, column 7 to 8) has been proposed. In such a method, it is considered that a surface roughness of the silicon layer of the SOI wafer may be reduced after the heat treatment.

However, since the heat treatment of the SIMOX method is performed at a temperature of 1000° C. or more, especially at a temperature of 1300° C. or more over several hours for forming a satisfactory BOX layer, if the SOI substrate is heat treated in a pure oxygen atmosphere as in Patent Reference 4, oxide film having a thickness of at least 1 μm is formed on the surface of the SOI substrate. Where the thickness of the oxide film is 1 μm or more, in order to ensure the silicon layer remaining at the opposite side of the silicon base layer with the insulation layer in between, it is necessary to form an epitaxial silicon layer after the oxygen implantation. Such an additional process causes a complication of production process and increase of production cost. Therefore, it is necessary to reduce the surface roughness of the silicon layer without multiplying the production process of the SOI substrate.

An object of the present invention is to reduce the surface roughness of the silicon layer of the SOI substrate after heat treatment without multiplying the production process.

### SUMMARY OF THE INVENTION

In order to solve the above-described problem, a method for producing an SOI substrate according to the invention comprises: implanting oxygen ions into a silicon substrate; forming a buried oxide film in the silicon substrate by a heat treatment of the silicon substrate in an inert atmosphere containing inert gas and oxygen, wherein the inert gas contains argon and nitrogen. In accordance with such a method for producing an SOI substrate, it is possible to reduce the surface-roughness of a silicon layer of the SOI substrate after the heat-treatment without multiplying the production process.

In the above-described inert atmosphere, the inert gas may be a mixture of argon and nitrogen. The mixture may be composed such that a proportion of a flow rate of nitrogen to the total flow rate of nitrogen and argon is not less than 1% and less than 50%. By using such an inert gas it is possible to ensure the reduction of the surface roughness of the silicon layer of the SOI substrate after the heat-treatment.

In addition, in the above-described inert gas composed of argon and nitrogen, nitrogen and argon may be mixed such that the proportion of the flow rate of nitrogen to the total flow rate of nitrogen and argon is not less than 20% and not more than 40%. Use of such an inert gas in the above described method for producing an SOI substrate is preferable since the surface roughness of the silicon layer of the SOI substrate after the heat-treatment can be reduced to a level equal to or lower than that of the SOI substrate before the heat-treatment.

In the above-described inert gas composed of nitrogen and argon, nitrogen and argon may be mixed such that the proportion of the flow rate of nitrogen to the total flow rate of nitrogen and argon is not less than 1% and less than 40%. By using such an inert gas in the above described method for producing an SOI substrate, interface roughness (roughness of an interface) between the buried oxide film and the silicon layer may also be reduced in addition to the reduction of the surface roughness of the silicon layer of the SOI substrate after the heat-treatment.

In the above-described inert gas, nitrogen and argon may be mixed such that the proportion of the flow rate of nitrogen to the total flow rate of nitrogen and argon is not less than 20% and not more than 30%. By using such an inert gas in the above described method for producing an SOI substrate, interface roughness between the buried oxide film and the silicon layer may also be reduced in addition to the reduction of the surface roughness of the silicon layer of the SOI substrate after the heat-treatment to a level less than or equal to that of the SOI substrate before the heat-treatment.

An SOI substrate of the present invention may comprise: a silicon base layer; an insulation layer consisting of a buried oxide layer formed on one side of the silicon base layer; and a silicon layer formed on the insulation layer on the opposite side with respect to the silicon base layer, wherein a roughness of a measurement area of 1 μm square on a surface of the silicon layer is 2 Å or less in RMS value. By the above-described constitution, it is possible to improve the quality of the SOI substrate.

In addition, the SOI substrate may have a constitution such that the roughness of a measurement area of 1 μm square may be 2 Å or less in RMS value both on a surface of the silicon layer and on an interface between the silicon layer and the buried oxide layer. By the above-described constitution, it is possible to further enhance a quality thereof.

According to the invention, it is possible to reduce the surface-roughness of the silicon layer of an SOI substrate after the heat treatment without multiplying the production process of the SOI substrate.

### BRIEF DESCRIPTION OF THE DRAWINGS

FIG. 1 is a drawing, by schematic cross sections of a substrate, showing a production process of an SOI substrate according to an embodiment of the invention.

FIG. 2 is a graph showing the influence of nitrogen concentration in an inert atmosphere on a roughness of a measurement area of 1 μm square on a surface of the silicon layer of an SOI substrate.

FIG. 3 is a graph showing the influence of nitrogen concentration in an inert atmosphere on the roughness of a measurement area of 1 μm square on an interface between a BOX layer and a silicon layer of an SOI substrate.

FIG. 4 is a graph showing the influence of nitrogen concentration in an inert atmosphere on the haze of a silicon substrate not implanted with oxygen ions.

### DETAILED DESCRIPTION OF THE INVENTION

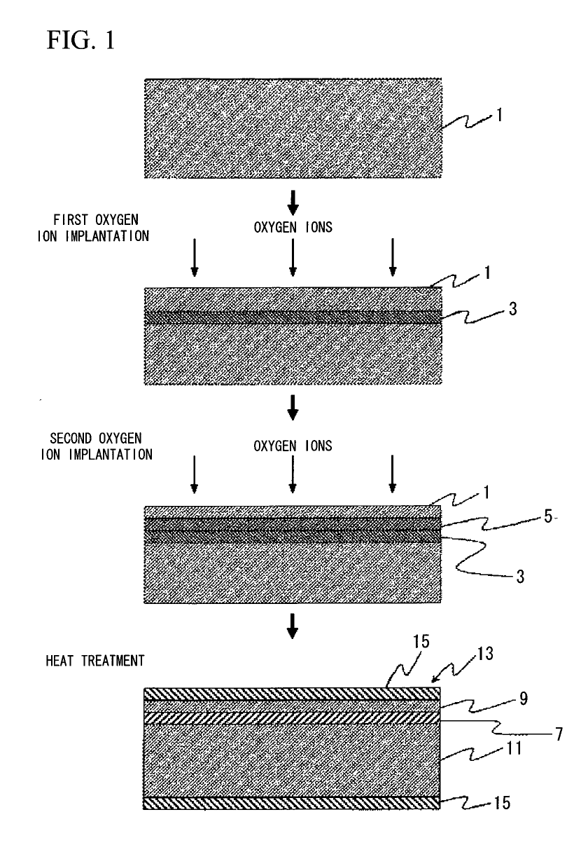

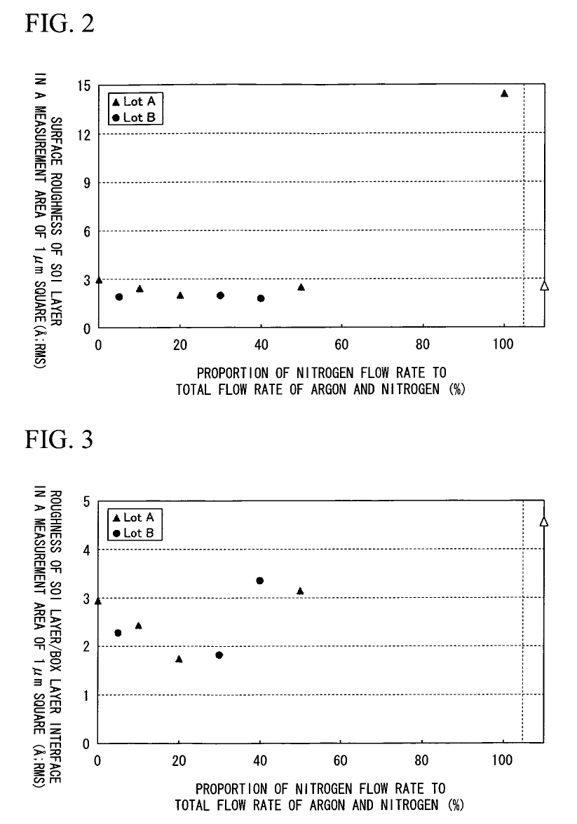

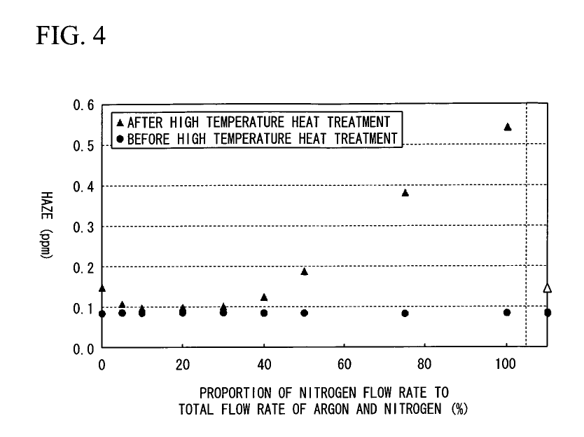

In the following, an embodiment of a method for producing an SOI wafer in accordance with the present invention is explained with reference to FIGS. 1 to 4. FIG. 1 indicates schematic cross sections of a substrate, showing a production process of an SOI substrate in accordance with the present invention. FIG. 2 is a graph showing the influence of nitrogen concentration in an inert atmosphere on the roughness of a measurement area of 1 μm square on a surface of the silicon layer of an SOI substrate. FIG. 3 is a graph showing the influence of nitrogen concentration in an inert atmosphere on the roughness of a measurement area of 1 μm square on the interface between a BOX layer and a silicon layer of an SOI substrate. FIG. 4 is a graph showing the influence of nitrogen concentration in an inert atmosphere on the haze of a silicon substrate not implanted with oxygen ions.

In the present embodiment, the method for producing an SOI wafer is explained by an example of a production of a SIMOX wafer as an SOI substrate using the MLD(Modified Low Dose)-SIMOX(Separation by Implanted Oxygen) method accompanied with two steps of oxygen implantation. However, it should be noted that the present invention is not limited to MLD-SIMOX method, but can be applied to the other SIMOX methods such as ITOX(Internal Thermal Oxidation)-SIMOX method.

The present embodiment of the method for producing an SOI substrate applying the MLD-SIMOX method, as shown in FIG. 1, comprises: a first oxygen implantation for implanting oxygen ions into a silicon substrate 1 for forming a SIMOX wafer; a second oxygen implantation performed after the first oxygen implantation; and a heat-treatment performed after the second oxygen implantation. The first oxygen implantation is a step for implanting oxygen ions into the silicon substrate 1 while heating the silicon substrate 1. While maintaining the surface of the silicon substrate 1 at a single crystalline state by heating the silicon substrate 1, a high-oxygen concentration layer 3 is formed in the silicon substrate 1. The second ion implantation is a step for implanting oxygen ions into the silicon substrate 1 after lowering the temperature of the silicon substrate 1 to nearly a room temperature, thereby forming an amorphous layer 5.

In the heat treatment, in a mixed gas atmosphere of oxygen and inert gas, heat treatment temperature was set at not lower than 1100° C., preferably not lower than 1300° C., for example at 1320 to 1350° C. In that condition, the silicon substrate implanted with oxygen is subjected to oxidation treatment for 6-12 hours. As a result, an insulation layer consisting of a buried oxide film, that is a BOX (Buried Oxide) layer 7 is formed in the silicon substrate. By the above-described process, a SIMOX wafer 13 having an SOI structure is formed such that a silicon layer, that is SOI layer 9, exists on one side of the BOX layer 7, and silicon base layer 11 exists on the other side of the BOX layer 7. In the above described process, by controlling a partial pressure of oxygen in the oxidation process or the retention time during the heat treatment, the thickness of the SOI layer 9 may be controlled by controlling the thickness of a surface oxide film 15 formed on the surface of the SIMOX wafer.

In the heat treatment performed in the present embodiment, a mixed gas of argon and nitrogen is used as an inert gas mixed with oxygen. As a result of the inventor's investigation on the atmosphere during the heat treatment, it was found that roughness could be reduced by performing the heat treatment in a mixed gas atmosphere containing an inert gas composed of the mixed gas of argon and nitrogen and oxygen mixed with the inert gas. The effect of the above-described atmosphere can be interpreted as following. By the nitrogen component in the atmosphere during the heat treatment, a small amount of nitrogen is contained in the surface oxide film 15 and inhibits sublimation of SiO. In addition, an argon component in the atmosphere inhibits formation of nitroxide.

It was also found that the degree of reduction of the roughness changes depending on the mixing ratio of argon and nitrogen in the inert gas constituting the atmosphere of the heat treatment, and that by controlling the mixing ratio of argon and nitrogen, it was possible to reduce interface-roughness between the SOI substrate and the BOX layer, as well as the surface roughness of the SOI layer of the SOI substrate.

Therefore, in the method for producing an SOI substrate of the present embodiment, in order to reduce the surface roughness of the surface of SOI layer 9 of the SIMOX wafer 13 after the heat treatment, the mixed gas of argon and nitrogen is used as an inert gas in the atmosphere of the heat treatment. At that time, argon and nitrogen is mixed such that the proportion of nitrogen flow rate in the total flow rate of argon and nitrogen is 1% or more, and less than 50%.

In addition, if it is necessary to reduce the surface roughness of the SOI layer 9 of the SIMOX wafer 13 after the heat treatment to a level less than or equal to that of the SOI substrate before the heat treatment, inert gas in the atmosphere of the heat treatment may be controlled such that the proportion of nitrogen flow rate in the total flow rate of argon and nitrogen is 20% or more, and 40% or less.

If it is necessary to reduce the interface roughness between the SOI layer 9 and the BOX layer 7 of the SIMOX wafer 13, in addition to the reduction of surface roughness of the SOI layer 9, inert gas in the atmosphere of the heat treatment may be controlled such that the proportion of nitrogen flow rate in the total flow rate of argon and nitrogen is 1% or more, and less than 40%.

If it is necessary to reduce the interface roughness between the SOI layer 9 and the BOX layer 7 of the SIMOX wafer 13, in addition to the reduction of the surface roughness of the SOI layer 9 of the SIMOX wafer 13 after the heat treatment to a level equal to or lower than that of the SOI substrate before the heat treatment, inert gas in the atmosphere of the heat treatment may be controlled such that the proportion of nitrogen flow rate in the total flow rate of argon and nitrogen is 20% or more, and 40% or less.

On the other hand, in the method for producing an SOI substrate of the present embodiment, in the SIMOX wafer 13 formed by controlling the inert gas in the atmosphere of the heat treatment such that the proportion of nitrogen flow rate in the total flow rate of argon and nitrogen is 20% or more, and 40% or less, and the roughness of a measurement area of 1 μm square on a surface of the SOI layer 9 is 2 Å or less in RMS value. Therefore, the surface roughness of the SOI layer 9 of the SIMOX wafer 13 of the present embodiment is not larger than the roughness of the surface of the silicon substrate before the heat treatment.

Where necessary, in the SIMOX wafer 13, the roughness of a measurement area of 1 μm square may be 2 Å or less in RMS value both on a surface of the SOI layer 9 and an interface between the SOI layer 9 and the BOX layer 7. It can be achieved by controlling the inert gas in the atmosphere of the heat treatment such that the proportion of nitrogen flow rate in total flow rate of argon and nitrogen is 20% or more, and 30% or less.

In the present embodiment, procedure, acceleration energy, and dosage of oxygen ions in the first oxygen implantation and the second oxygen implantation were similar to those of the conventional method. Procedure in the heat treatment and oxygen content in the atmosphere were also similar to those of the conventional method.

Preferably, proportion of a flow rate of oxygen to the total flow rate of inert gas and oxygen is not less than 0.5% and not more than 70%. More preferably, the proportion of the flow rate of oxygen to the total flow rate of inert gas and oxygen is not less than 0.5% and not more than 50%. In order to form an oxide film acting as a protective film on the surface of the wafer, at least 0.5% of oxygen is required. On the other hand, where too much oxygen is contained in the inert atmosphere, it is necessary to form an epitaxial silicon layer after the implantation of oxygen ions so as to ensure the presence of SOI layer. Such an additional step complicates the production process and increase the production cost of the SOI substrate.

Dependencies of the surface roughness of the SOI layer 9 and interface roughness between the SOI layer 9 and the BOX layer 7 on the mixing ratio of argon and nitrogen in the inert gas constituting the atmosphere of the heat treatment were subjected to the examination. An example result of the examination is explained in the following. Where a mixed gas of argon and oxygen was used, as in a conventional case, as the atmosphere of the heat treatment, that is, where the inert gas was composed of 100% of Ar and 0% of nitrogen, as shown in FIG. 2, the roughness of a measurement area of 1 μm square on a surface of the SOI layer was about 3 Å in RMS value. On the other hand, by using a mixed gas of argon and nitrogen as the inert gas in the atmosphere of the heat treatment, and by controlling the mixing ratio of the inert atmosphere such that the proportion of nitrogen flow rate in the total flow rate of argon and nitrogen was 1% or more, and less than 50%, surface roughness of the SOI layer 9 was effectively reduced such the roughness of a measurement area of 1 μm square on a surface of the SOI layer was smaller than 3 Å in RMS value.

In addition, by using a mixed gas of argon and nitrogen as the inert gas in the atmosphere of the heat treatment, and by controlling the mixing ratio of the inert atmosphere such that the proportion of nitrogen flow rate in the total flow rate of argon and nitrogen was 20% or more, and 40% or less, roughness of a measurement area of 1 μm square on a surface of the SOI layer 9 was 2 Å or less in RMS value, and the surface roughness of the SOI layer 9 was reduced to a level less than or equal to that of the surface of the silicon substrate 1 before the heat treatment. It is considered that the small nitrogen content in the surface oxide film 15 inhibited sublimation of SiO.

Where the proportion of nitrogen flow rate in the total flow rate of argon and nitrogen was less than 1%, surface roughness of the SOI substrate 9 could not be reduced as in the conventional case using an inert gas composed of 100% of Ar. Where the proportion of nitrogen flow rate in the total flow rate of argon and nitrogen was 50% or more, because of increasing formation of nitroxide, it was impossible to reduce the surface roughness of the SOI layer 9. Where the inert gas was composed of 100% of nitrogen, roughness of a measurement area of 1 μm square on a surface of the SOI layer 9 showed a large value up to about 15 Å in RMS value. In the example shown in FIG. 2, the case in which the proportion of nitrogen flow rate to total flow rate of argon and nitrogen was 50% and more, the surface roughness of the SOI layer 9 was almost the same as in the case shown by the open triangle in FIG. 2, where a mixed gas of nitrogen and oxygen was used as an atmosphere of the heat-up process of the heat treatment, and a mixed gas of argon and oxygen was used as an atmosphere of the retention process at a constant temperature and of the subsequent process of the heat treatment. That is, where a mixed gas of nitrogen and oxygen was used as an atmosphere of the heat-up process of the heat treatment, and a mixed gas of argon and oxygen was used as an atmosphere of the retention process at a constant temperature and of the subsequent process of the heat treatment, the roughness of a measurement area of 1 μm square on a surface of the SOI layer 9 was about 2.5 Å in RMS value.

On the other hand, where a mixed gas of argon and oxygen was used, as in a conventional case, as the atmosphere of the heat treatment, that is, where the inert gas was composed of 100% of Ar and 0% of nitrogen, as shown in FIG. 3, the roughness of a measurement area of 1 μm square on a interface between the SOI layer 9 and the BOX layer 7 was about 3 Å in RMS value. However, by using a mixed gas of argon and nitrogen as the inert gas in the atmosphere of the heat treatment, and by controlling the mixing ratio of the inert atmosphere such that the proportion of nitrogen flow rate in the total flow rate of argon and nitrogen was 1% or more, and less than 40%, the interface roughness between the SOI layer and the BOX layer was reduced such that the roughness of a measurement area of 1 μm square on a interface between the SOI layer 9 and the BOX layer 7 was less than 3 Å in RMS value.

In addition, by using a mixed gas of argon and nitrogen as the inert gas in the atmosphere of the heat treatment, and by controlling the mixing ratio of the inert atmosphere such that the proportion of nitrogen flow rate in the total flow rate of argon and nitrogen was 20% or more, and 30% or less, the interface roughness between the SOI layer 9 and the BOX layer 7 was further reduced such that roughness of a measurement area of 1 μm square on an interface between the SOI layer 9 and the BOX layer 7 was 2 Å or less in RMS value.

On the other hand, where the proportion of nitrogen flow rate in the total flow rate of argon and nitrogen was less than 1%, the interface roughness between the SOI substrate 9 and the BOX layer 7 could not be reduced as in the conventional case using an inert gas composed of 100% of Ar. Where the proportion of nitrogen flow rate in the total flow rate of argon and nitrogen was 40% or more, the roughness of a measurement area of 1 μm square on an interface between the SOI layer 9 and the BOX layer 7 was 3 Å or more in RMS value. In the case shown by the open triangle in FIG. 3, where a mixed gas of nitrogen and oxygen was used as an atmosphere of the heat-up process of the heat treatment, and a mixed gas of argon and oxygen was used as an atmosphere of retention process at a constant temperature and of the subsequent process of the heat treatment, roughness of a measurement area of 1 μm square on an interface between the SOI layer 9 and the BOX layer 7 was about 4.6 Å in RMS value. It is considered that the behavior of the interface roughness between the SOI layer 9 and the BOX layer depends on a similar mechanism as the behavior of the above-described surface roughness of the SOI layer 9.

FIG. 4 shows an example of a result of examination of an influence of nitrogen concentration in an inert atmosphere on the haze of a silicon substrate not implanted with oxygen ions. The evaluation of the haze was equivalent to the evaluation of the roughness in a measurement area of 1 μm square.

Where a mixed gas of argon and oxygen was used, as in a conventional case, as the atmosphere of the heat treatment, that is, where the inert gas was composed of 100% of Ar and 0% of nitrogen, a silicon substrate showed a haze of 0.15 ppm after a similar heat treatment as the SIMOX method, whereas the haze of the silicon substrate before the heat treatment was 0.09 ppm. However, by using a mixed gas of argon and nitrogen as the inert gas in the atmosphere of the heat treatment, and by controlling the mixing ratio of the inert atmosphere such that the proportion of nitrogen flow rate in the total flow rate of argon and nitrogen was 1% or more, and less than 50%, the haze of the silicon substrate after the heat treatment was reduced to a level lower than 0.15 ppm. Moreover, by controlling the mixing ratio of the inert atmosphere such that the proportion of nitrogen flow rate in the total flow rate of argon and nitrogen was 10% or more, and 30% or less, the haze of the silicon substrate after the heat treatment was further reduced to a level not more than 0.1 ppm.

On the other hand, where the proportion of nitrogen flow rate in total flow rate of argon and nitrogen was reduced to a level less than 1%, or increased to a level of 50% or more, the haze of the silicon substrate was increased. Where, a mixed gas of nitrogen and oxygen was used, that is, where the inert gas was composed of 100% of nitrogen, the haze was increased to about 0.55 ppm. In an example shown in FIG. 4, haze was about 0.15 ppm in the case indicated by the open triangle, where a mixed gas of nitrogen and oxygen was used as an atmosphere of the heat-up process of the heat treatment, and mixed gas of argon and oxygen was used as an atmosphere of the retention process at a constant temperature and of the subsequent process of the heat treatment.

The above-described behavior of the haze is correlated to the behavior of the surface roughness of the SOI layer of the SIMOX wafer, shown by the roughness of a measurement area of 1 μm square. Therefore, it can be considered that the use of mixed gas of argon and nitrogen as the inert gas does not inhibit the roughness accompanied with the formation of the BOX layer, but as described-above, inhibits the roughness caused by sublimation of SiO enhanced by argon, or the formation of nitroxide caused by nitrogen.

As explained above, in accordance with the method of producing an SOI substrate of the present embodiment, by using a mixed gas of argon and nitrogen as the inert gas constituting the atmosphere of the heat treatment, without performing an additional step, for example, a step for forming an epitaxial silicon layer after the oxygen implantation, it is possible to reduce the surface roughness of the SOI layer 9. Therefore, it is possible to reduce a surface roughness of a silicon layer of the SOI substrate after the heat treatment without multiplying the production process.

At that time, by controlling the mixing ratio of the inert atmosphere such that the proportion of nitrogen flow rate in the total flow rate of argon and nitrogen was 1% or more, and less than 50%, it is possible to ensure the reduction of surface roughness of the silicon layer of the SOI substrate.

In addition, since the surface roughness of the silicon layer is reduced without multiplying the production process, it is possible to reduce the roughness without causing an increase of production cost or complication of the production process.

In addition, by controlling the mixing ratio of the inert atmosphere of the heat treatment such that the proportion of nitrogen flow rate in the total flow rate of argon and nitrogen was 20% or more, and 40% or less, it is possible to reduce the surface roughness of the silicon layer of the SOI substrate after the heat treatment to a level less than or equal to the surface roughness of the silicon layer of the SOI substrate before the heat treatment.

By the above-described method, at low cost, it is possible to produce a SIMOX wafer as an SOI substrate such that the roughness of a measurement area of 1 μm square on a surface of the silicon layer is 2 Å or less in RMS value. As a result it is possible to enhance the quality of an SOI substrate.

In addition, by controlling the mixing ratio of the inert atmosphere of the heat treatment such that the proportion of flow rate of nitrogen to the total flow rate of nitrogen and argon is not less than 1% and less than 40%, it is possible to reduce the interface roughness between the buried oxide film and the silicon layer in addition to the reduction of the surface roughness of the silicon layer of the SOI substrate after the heat-treatment.

Moreover, by using the mixed gas of nitrogen and argon such that the proportion of flow rate of nitrogen to the total flow rate of nitrogen and argon is not less than 20% and not more than 30%, it is possible to further reduce the interface roughness between the buried oxide film and the silicon layer in addition to the reduction of the surface roughness of the silicon layer of the SOI substrate after the heat-treatment to a level less than or equal to that of the SOI substrate before the heat-treatment. By the above-described method, at low cost, it is possible to produce a SIMOX wafer as an SOI substrate such that a roughness of a measurement area of 1 μm square both on a surface of a silicon layer and an interface between the silicon layer and a buried oxide film was 2 Å or less in RMS value. As a result, it is possible to further enhance the quality of an SOI substrate.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. For example, the invention may be applied to a method for producing an SOI substrate by various SIMOX methods performing heat treatment to form a BOX layer consisting of a buried oxide film. In addition, the invention can be applied to SOI substrates of various structure comprising: a silicon base layer; an insulation layer consisting of a buried oxide film formed on one side of the silicon base layer; and a silicon layer formed on the insulation layer on the opposite side with respect to the base layer.

Accordingly, the invention is not to be considered as being limited by the foregoing description, and is only limited by the scope of the appended claims.

What is claimed is:

1. A method for producing an SOI substrate, comprising:
implanting oxygen ions into a silicon substrate;
heat treating the silicon substrate in an inert atmosphere containing inert gas and oxygen; and
forming a buried oxide film in the silicon substrate, wherein the inert gas contains argon and nitrogen.

2. A method for producing an SOI substrate according to claim 1, wherein the inert gas is a mixture of argon and nitrogen and is composed such that a proportion of flow rate of nitrogen in the total flow rate of argon and nitrogen is 1% or more, and less than 50%.

3. A method for producing an SOI substrate according to claim 1, wherein the inert gas is a mixture of argon and nitrogen and is composed such that a proportion of nitrogen flow rate in the total flow rate of argon and nitrogen is 20% or more, and 40% or less.

4. A method for producing an SOI substrate according to claim 1, wherein the inert gas is a mixture of argon and nitrogen and is composed such that a proportion of nitrogen flow rate in the total flow rate of argon and nitrogen is 1% or more, and less than 40%.

5. A method for producing an SOI substrate according to claim 1, wherein the inert gas is a mixture of argon and nitrogen and is composed such that a proportion of nitrogen flow rate in the total flow rate of argon and nitrogen is 20% or more, and 30% or less.

6. An SOI substrate comprising:
a silicon base layer;
an insulation layer consisting of a buried oxide film formed on one side of the silicon base layer; and
a silicon layer formed on the insulation layer on the opposite side with respect to the base layer, wherein
the roughness of a measurement area of 1 μm square on a surface of the silicon layer is 2 Å or less in RMS value.

7. An SOI substrate comprising:
a silicon base layer;
an insulation layer consisting of a buried oxide film formed on one side of the silicon base layer; and
a silicon layer formed on the insulation layer on the opposite side with respect to the base layer, wherein
both of the roughness of a measurement area of 1 μm square on a surface of the silicon layer and the roughness of a measurement area of 1 μm square on an interface between the insulation layer and the silicon layer is 2 Å or less in RMS value.
